(19) United States
(12) Patent Application Publication
(10) Pub. No.: US 2025/0081499 A1
(43) Pub. Date: Mar. 6, 2025

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Shih-Yen LIN, New Taipei City (TW); Che-Jia CHANG, Taichung City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/459,079

(22) Filed: Aug. 31, 2023

(51) Int. Cl. H01L 29/66; H01L 29/18; H01L 29/417; H01L 29/423; H01L 29/786

(52) U.S. Cl. CPC H10D 30/031; H10D 30/6729; H10D 30/673; H10D 30/6757; H10D 62/84

(57) ABSTRACT

A method includes forming a gate electrode in contact with a gate dielectric layer; forming a first 2-D material buffer layer over the gate dielectric layer; forming a 2-D material channel layer over the first 2-D material buffer layer; and forming source/drain electrodes over source/drain regions of the 2-D material channel layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D illustrate a semiconductor device in various stages of fabrication in accordance with some embodiments of the present disclosure.

FIG. 2 illustrates a schematic view of a mono-layer of a TMD in accordance with some embodiments of the present disclosure.

FIG. 3 shows an experiment result of a semiconductor device in accordance with some embodiments of the present disclosure.

FIGS. 4A to 4D show experiment results of a semiconductor device in accordance with some embodiments of the present disclosure.

FIGS. 5A and 5B show experiment results of semiconductor devices in accordance with some embodiments of the present disclosure.

FIG. 6 shows an experiment result of a semiconductor device in accordance with some embodiments of the present disclosure.

FIG. 7 illustrates a semiconductor device in accordance with some embodiments of the present disclosure.

FIG. 8 shows an experiment result of a semiconductor device in accordance with some embodiments of the present disclosure.

FIG. 9 illustrates a semiconductor device in accordance with some embodiments of the present disclosure.

FIG. 10 shows an experiment result of a semiconductor device in accordance with some embodiments of the present disclosure.

FIG. 11 illustrates a semiconductor device in accordance with some embodiments of the present disclosure.

FIG. 12 shows an experiment result of a semiconductor device in accordance with some embodiments of the present disclosure.

FIGS. 13A to 13F illustrate a semiconductor device in various stages of fabrication in accordance with some embodiments of the present disclosure.

FIGS. 14A to 14B illustrate semiconductor devices in accordance with some embodiments of the present disclosure.

FIG. 15 shows an experiment result of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

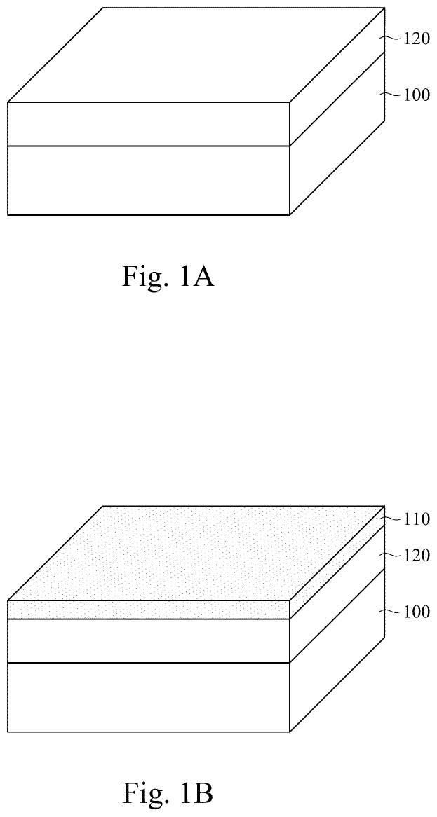

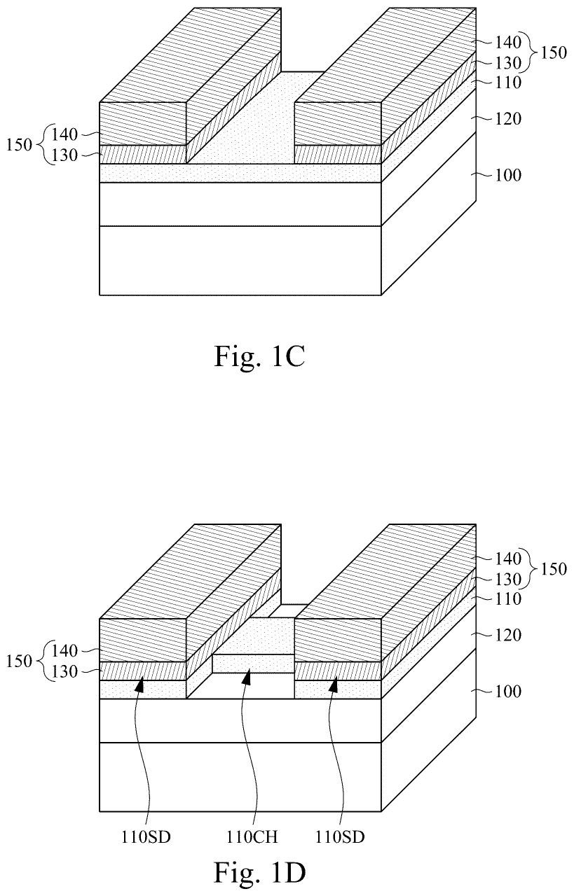

FIGS. 1A to 1D illustrate a semiconductor device in various stages of fabrication in accordance with some embodiments of the present disclosure.

Reference is made to FIG. 1A. Shown there is a substrate 100. In some embodiments, the substrate 100 may be a conductive substrate, such as polysilicon. For example, the substrate 100 may be made of p-doped polysilicon. A dielectric layer 120 is formed over the substrate 100. In some embodiments, the dielectric layer 120 is silicon dioxide (e.g., SiO₂) or aluminum oxide (Al₂O₃), while in other embodiments the dielectric layer 120 may be a high-k dielectric. In some embodiments, the substrate 100 may serve as a gate electrode of a transistor and the dielectric layer 120 may act a gate dielectric layer of a transistor. Accordingly, the substrate 100 can also be referred to as a gate electrode, and the dielectric layer 120 can also be referred to as a gate dielectric layer. In some embodiments, the dielectric layer 120 and the substrate 100 can be collectively referred to as a gate structure.

Reference is made to FIG. 1B. A 2-D material channel layer 110 is formed over the dielectric layer 120. As used herein, consistent with the accepted definition within solid state material art, a “2-D material” may refer to a crystalline material consisting of a single layer of atoms. As widely accepted in the art, “2-D material” may also be referred to as a “monolayer” material. In this content, “2-D material” and “monolayer” material are used interchangeably without differentiation in meanings, unless specifically pointed out otherwise. The 2-D material layer may be 2-D materials of suitable thickness. In some embodiments, a 2-D material includes a single layer of atoms in each of its monolayer structure, so the thickness of the 2-D material refers to a number of monolayers of the 2-D material, which can be one monolayer or more than one monolayer. The coupling between two adjacent monolayers of 2-D material includes van der Waals forces, which are weaker than the chemical bonds between/among atoms within the single monolayer. In some embodiments, the 2-D material layer may be a single monolayer structure, or may also be a multi-layer structure.

In some embodiments, the 2-D material channel layer 110 may be made of transition metal dichalcogenides (TMDs). That is, the 2-D material channel layer 110 may be a metal-containing 2-D material layer. In some embodiment where the 2-D material channel layer 110 includes TMDs monolayer, the TMDs monolayer include molybdenum disulfide (MoS₂), molybdenum diselenide (MoSe₂) molybdenum ditelluride (MoTe₂), tungsten disulfide (WS₂), tungsten diselenide (WSe₂), tungsten ditelluride (WTe₂), or the like.

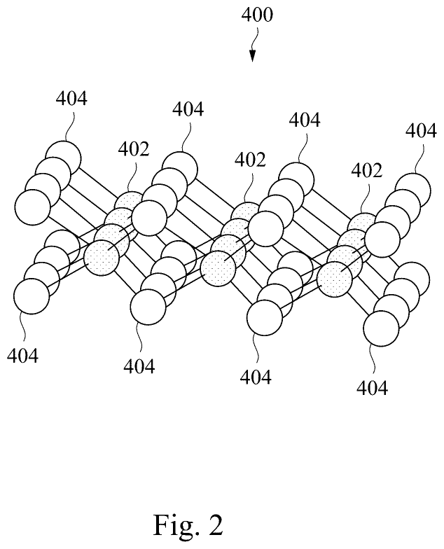

Referring to FIG. 2. FIG. 2 illustrates a schematic view of a mono-layer 400 of an example TMDs in accordance with some example embodiments. In FIG. 2, the one-molecule thick TMDs material layer includes transition metal atoms 402 and chalcogen atoms 404. The transition metal atoms 402 may form a layer in a middle region of the one-molecule thick TMDs material layer, and the chalcogen atoms 404 may form a first layer over the layer of transition metal atoms 402, and a second layer underlying the layer of transition metal atoms 402. The transition metal atoms 402 may be W atoms or Mo atoms, while the chalcogen atoms 404 may be S atoms, Se atoms, or Te atoms. Throughout the description, the illustrated cross-bonded layers including one layer of transition metal atoms 402 and two layers of chalcogen atoms 404 in combination are referred to as a mono-layer 400 of TMDs.

Referring back to FIG. 1B, the 2-D material channel layer 110 may be made of MoS₂, and the MoS₂ may be formed using the methods described below. Although MoS₂ has exhibited potential applications in optical and electrical devices, most devices may be fabricated with small MoS₂ flakes in micrometer sizes prepared through either mechanical exfoliation or chemical vapor deposition (CVD). These methods are not scalable and would hinder the practical application of MoS₂-based devices. To solve this problem, it has been proposed that wafer-scale MoS₂ films can be obtained through the sulfurization of pre-deposited Mo or MoO₃ thin films. Layer number can be well controlled by using such method. One possible concern on the two-stage growth process of MoS₂ is that a thin Mo/MoO₃ film down to 1.0 nm is usually required to achieve mono-layer MoS₂ growth. In this case, the coverage of the Mo/MoO₃ film may not be uniform across the substrate, which may lead to non-uniform or broken MoS₂ film growth after the sulfurization process.

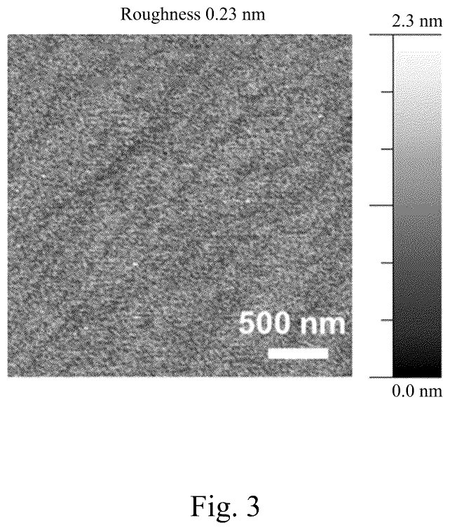

To achieve uniform MoO₃ growth for following sulfurization, an atomic layer deposition technique (ALD) may be adopted for forming the 2-D material channel layer 110 made of MoS₂. Two precursors, molybdenum hexacarbonyl (Mo(Co)₆) and ozone (O₃) are adopted for MoO₃ growth. The carrier gas for the ALD system is nitrogen and the growth temperature is about 180° C. A deposition cycle for the ALD process involves following steps: (a) a 9-second pulse of Mo(Co)₆, (b) a 3-second purge with nitrogen, (c) a 9-second pulse of O₃, and (d) a 6-second purge with nitrogen. In some embodiments, for a mono-layer MoS₂, 6 ALD growth cycles are adopted for MoO₃ growth. After the MoS₃ film is formed, a sulfurization is performed to the MoO₃ film to form the MoS₂ film. As shown in FIG. 3, an atomic-flat surface is observed for the sample with surface roughness about 0.23 nm. The results have demonstrated that uniform MoS₂ films can be grown on a substrate by sulfurizing the MoO₃ films prepared by ALD.

On the other hand, one major advantage of 2-D material is that the thin film can be transferred to different substrates and still maintain their unique electrical and optical characteristics after the film transferring process. Compared with conventional PMMA-assisted film transferring process, the film transferring process by using the PDMS stamping can significantly reduce the PMMA contaminations on 2-D material surface.

In a typical PDMS stamping, a polydimethylsiloxane (PDMS) elastomer stamp is used as a carrier substrate for the material (e.g., the 2-D material channel layer 110 in this case) to be deposited. In some embodiments, the 2-D material channel layer 110 (e.g., MoS₂) is coated on a protruding surface of a PDMS stamp. The 2-D material channel layer 110 is transferred to a substrate (e.g., the dielectric layer 120 in this case), and the PDMS stamp is then peeled off from the 2-D material channel layer 110.

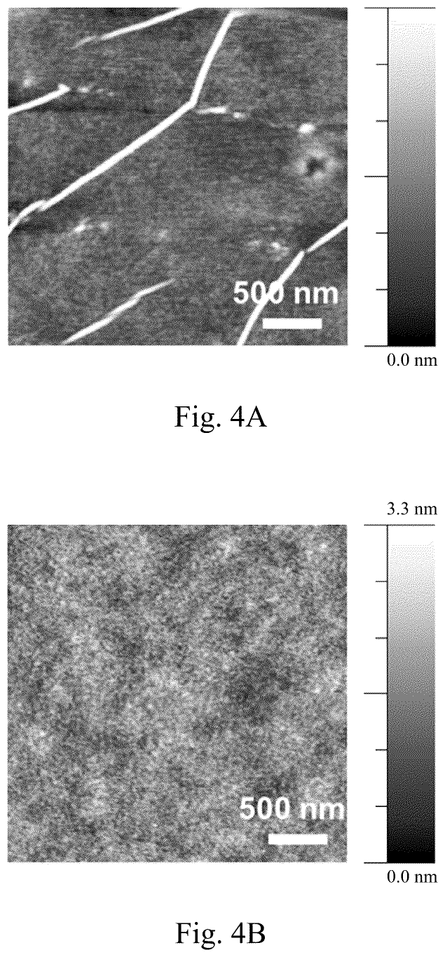

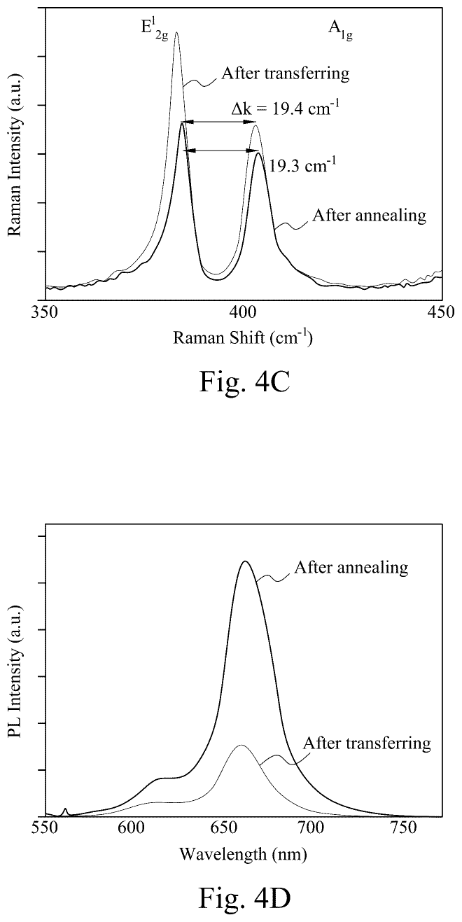

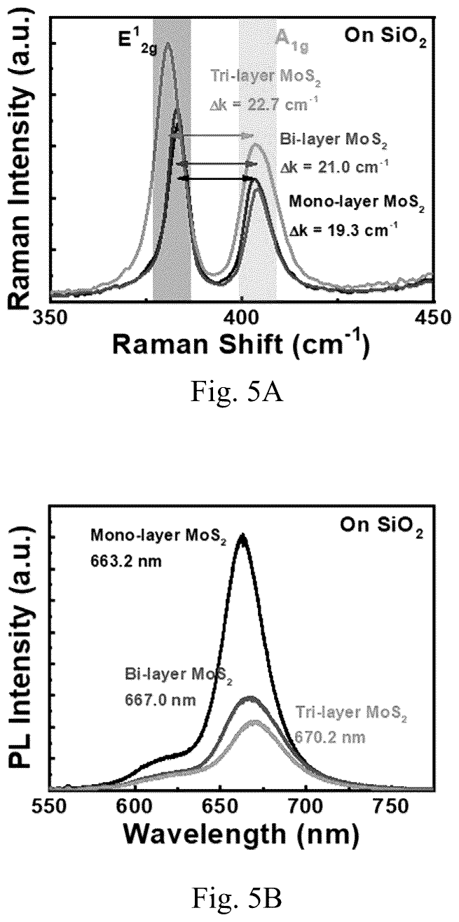

Reference is made to FIG. 4A, an AFM image of a MoS₂ film formed by PDMS stamping is shown. Compared with the flat as-grown MoS₂ sample (e.g., see FIG. 3), wrinkles are observed on the MoS₂ surface. The surface roughness of the sample is also increased to 0.55 nm. Since the MoS₂ film is only about one-few nanometers in thicknesses, the surface tension in the thin MoS₂ film after being transferred to a substrate may be the main mechanism responsible for this phenomenon.

To release the surface tension of the MoS₂ film, an annealing process is performed to the sample at about 100° C. to about 200° C. (e.g., 150° C.) for about 0.5 to 2 hours (e.g., 1.5 hours) under the Argon (Ar) environment. The AFM image of the sample after the annealing process is shown in FIG. 4B. Compared with FIG. 4A, the wrinkles are smoothed out after the annealing process, and the surface roughness is reduced to about 0.3 nm. The results suggest that the annealing process can effectively release the surface tension of the thin MoS₂ film and flatten its surface.

The Raman and photoluminescence (PL) spectra of the sample after the film transferring to a substrate and after the annealing process are shown in FIGS. 4C and 4D, respectively. As shown in the Raman spectra of FIG. 4C, E¹_{2g} and A1_{g} characteristic Raman peaks of MoS₂ are observed for the sample after the film transferring process and the additional annealing process. Similar Raman peak differences 19.4 and 19.3 cm⁻¹ of the sample after the film transferring process and the additional annealing process suggest that a mono-layer MoS₂ is obtained after the growth process. As shown in the PL spectra FIG. 4D, a much intense PL intensity is observed for the sample after the annealing process. One possible mechanism responsible for this phenomenon is the removal of water and oxygen molecules attached to the MoS₂ surface after the annealing process. Since the wrinkles observed in the sample after the transferring process are effectively a bi-layer MoS₂ (see FIG. 4A), a much intense PL intensity will also be observed from the flattened mono-layer MoS₂ film after the annealing process. The flattened MoS₂ film may potentially reduce the carrier scattering and enhance its performances for transistor applications.

FIGS. 5A and 5B show experiment results of semiconductor devices in accordance with some embodiments of the present disclosure.

To further investigate the flattened MoS₂ surface formed by PDMS stamping and annealing process, it is possible to take the advantage of the strong adhesion between MoS₂ layers and establish layer-number-controllable and multi-layer MoS₂ through sequential film attachment for device applications. By using the same PDMS stamping, one-, two-and three-MoS₂ films are transferred, one by one, to a substrate. After each film transferring, the same annealing process is performed at about 100° C. to about 200° C. (e.g., 150° C.) for about 0.5 to 2 hours (e.g., 1.5 hours) under the Argon (Ar) environment. The Raman spectra of the samples are shown in FIG. 5A, in which the E¹_{2g} and A1_{g} characteristic Raman peaks of MoS₂ are illustrated for the three samples. The differences of the two peaks increase from 19.3, 21.0 to 22.7 cm⁻¹ after one-, two- and three-times of MoS₂ transferring, which suggests that MoS₂ films with one-, two- and three-layers are obtained for the three samples. The results also suggest that the adhesion force between MoS₂ to MoS₂ and MoS₂ to the SiO₂ surface is stronger than the interface between PDMS and MoS₂, such that MoS₂ films may tend to attach to the substrate instead of to the PDMS surface after the transferring process. In this case, multi-layer MoS₂ films with good uniformity can be obtained after sequential film attachments. The PL spectra of the three samples are shown in FIG. 5B. The intense PL intensity of the sample with one-time MoS₂ transferring and the peak red shift with increasing MoS₂ layer numbers observed in the figure are also consistent with the observation from the Raman spectra that one-, two- and three-MoS₂ layers are obtained after one to three MoS₂ transferring process.

Reference is made to FIG. 1C. Source/drain electrodes 150 are formed over the 2-D material channel layer 110. In some embodiments, each of the source/drain electrodes 150 includes a first metal layer 130 and a second metal layer 140 over the first metal layer 130. The source/drain electrodes 150 may be formed by, for example, forming a photoresist layer with openings over the 2-D material channel layer 110, sequentially depositing the first metal layer 130 and the second metal layer 140 in the openings of the photoresist layer, and then performing a lift-off process to remove the photoresist layer and portions of the first metal layer 130 and the second metal layer 140 over the photoresist layer. As a result, the portions of the first metal layer 130 and the second metal layer 140 in the openings of the photoresist layer remain over the 2-D material channel layer 110 as the source/drain electrodes 150.

The first metal layer 130 and the second metal layer 140 may be made of different materials. In some embodiments, the first metal layer 130 is made of a single element 2-D material. For example, the first metal layer 130 is made of antimonene.

Specifically, antimonene is 2-D allotrope of antimony (Sb). In other embodiments, the first metal layer 130 may also include Bi, Sn, or Ge. In some embodiments, the deposition temperature of the first metal layer 130 can be ranged from 65° C. to about 75° C., such as 70° C. If the temperature is too low (e.g., much lower than 65° C.), the device performance may be unsatisfied. If the temperature is too high (e.g., much higher than 75° C.), the high temperature would deteriorate the quality of photoresist layer, and may adversely affect the formation of source/drain electrodes 150. By using antimonene as the contact electrode, significant contact resistance reduction can be observed at the interface between antimonene and 2-D material channel layer 110 (e.g., MoS₂). On the other hand, if standard photolithography and metal lift-off processes are adopted for Sb contact metal deposition, a relatively lower growth temperature (e.g., 70° C.) may be adopted for forming about 50 nm Sb deposition on the 2-D material channel surface instead of 200° C. required for single-crystal antimonene formation to prevent the photoresist deterioration. In some embodiments where the first metal layer 130 is made of antimonene under a deposition temperature ranged from 70° C. to about 80° C., the first metal layer 130 includes a polycrystalline structure rather than a single crystalline structure. Since the first metal layer 130 (e.g. Sb film) may be etched off in either alkaline or acidic solutions, the second metal layer 140, such as a 100 nm gold (Au) film, is deposited at room temperature (RT) after the deposition of the first metal layer 130 as a protection layer. In other embodiments, the second metal layer 140 may also include Cu and Pt.

Reference is made to FIG. 1D. Portion of the 2-D material channel layer 110 exposed through the source/drain electrodes 150 are patterned to define a channel region of a transistor. For example, the portion of the 2-D material channel layer 110 exposed through the source/drain electrodes 150 is narrowed down along a direction that is substantially perpendicular to a current flow direction. Here, the current flow direction may be the direction from one source/drain electrode 150 to another one source/drain electrode 150. As a result, a channel region 110CH is formed in the 2-D material channel layer 110. On the other hand, portions of the 2-D material channel layer 110 vertically below the source/drain electrodes 150 may be referred to as source/drain regions 110SD.

In some embodiments, reactive ion etching (RIE) may be adopted for the channel definition of the transistor after the source/drain electrodes 150 are formed. The channel width and length of the channel region are about 25 mm and 5 mm, respectively.

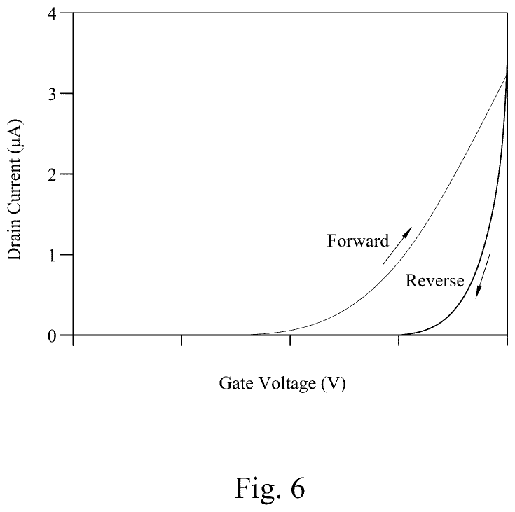

After the channel definition, a bottom gate transistor is formed. Here, the transistor may be a mono-layer MoS₂ transistor. The transfer curve of the device at V_{DS}=1.0 V is shown in FIG. 6. The field-mobility value derived from the transfer curve of the device is around 1.0 cm²·V⁻¹·s⁻¹. The value is much higher than the ˜10⁻² cm²·V⁻¹·s⁻¹ field-effect mobility of the transistor prepared by using the radio-frequency sputtering system. The results have demonstrated that a uniform MoO₃ film deposition by using ALD is critical for the growth of uniform 2-D material film (e.g., MoS₂) through the high-temperature sulfurization. Low contact resistance at the antimonene/MoS₂ interface can also be obtained such that improved device performances are observed for the transistor. However, as shown in FIG. 6, large hysteresis is observed for the device under forward and reverse gate biases.

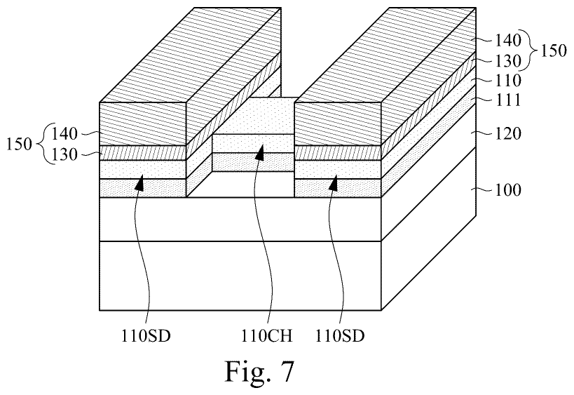

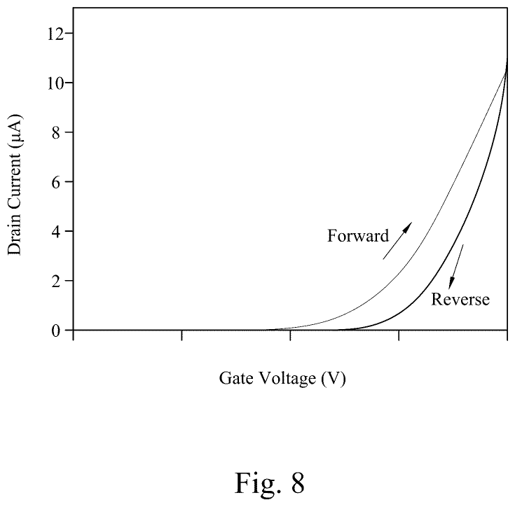

FIG. 7 illustrates a semiconductor device in accordance with some embodiments of the present disclosure. FIG. 8 shows an experiment result of a semiconductor device in accordance with some embodiments of the present disclosure. It is noted that some elements of FIG. 7 are similar to those described with respect to FIGS. 1A to 1D, such elements are labeled the same and relevant details are not repeated for brevity.

As discussed above with respect to FIGS. 1D and 6, one possible mechanism responsible for the large hysteresis loop observed for the mono-layer MoS₂ transistor may be the trap charges/dangling bonds on the dielectric surface at the interface between the 2-D material channel layer 110 (e.g., MoS₂) and the dielectric layer 120 (e.g., SiO₂). Therefore, to avoid the influence of the MoS₂/SiO₂ interface to the MoS₂ channel, a 2-D material buffer layer may be inserted between the 2-D material channel layer 110 and the dielectric layer 120.

In FIG. 7, a 2-D material buffer layer 111 is formed over the dielectric layer 120 prior to the formation of the 2-D material channel layer 110 as discussed in FIG. 1B. In some embodiments, the 2-D material buffer layer 111 and the 2-D material channel layer 110 may be patterned together during the channel definition process as discussed in FIG. 1D, and thus the 2-D material buffer layer 111 may include substantially a same profile as the 2-D material channel layer 110.

In some embodiments, the 2-D material buffer layer 111 may include a same material as the 2-D material channel layer 110, such as MoS₂, MoSe₂, MoTe₂, WS₂, WSe₂, WTe₂, or the like. In some other embodiments, the 2-D material buffer layer 111 may include a different material than the 2-D material channel layer 110. For example, the 2-D material buffer layer 111 may include a different TMD than the 2-D material channel layer 110. In some embodiments, the 2-D material channel layer 110 is made of MoS₂, while the 2-D material buffer layer 111 is made of WS₂. In other embodiments, the 2-D material buffer layer 111 may include hBN. In some embodiments, the 2-D material buffer layer 111 may include 1-10 monolayer(s).

In some embodiments, the 2-D material buffer layer 111 may be formed using an atomic layer deposition (ALD). In other embodiments, the 2-D material buffer layer 111 may be formed using a PDMS stamping followed by an annealing process to reduce a surface roughness of the 2-D material buffer layer 111. That is, when the 2-D material channel layer 110 and the 2-D material buffer layer 111 are both formed by PDMS stamping, a first PDMS stamping is performed to form the 2-D material buffer layer 111 over the dielectric layer 120, and a first annealing process is performed to smooth out the 2-D material buffer layer 111. Afterwards, a second PDMS stamping is performed to form the 2-D material channel layer 110 over the 2-D material buffer layer 111, and a second annealing process is performed to smooth out the 2-D material channel layer 110. Such method may ensure better film qualities for both the 2-D material channel layer 110 and the 2-D material buffer layer 111.

In an example of FIG. 7, a MoS₂ buffer layer (e.g., 2-D material buffer layer 111) is added between a MoS₂ channel (e.g., 2-D material channel layer 110) and a SiO₂ dielectric layer (e.g., dielectric layer 120). That is, a bi-layer MoS₂ film may be established on the SiO₂ surface through two times of mono-layer MoS₂ transferring. After the film transferring, the same electrodes (e.g., source/drain electrodes 150) are fabricated on the top of the bi-layer MoS₂ film. The transfer curve of the device at V_{DS}=1.0 V is shown in FIG. 8. Compared with the mono-layer MoS₂ transistor as discussed in FIG. 1D, the bi-layer MoS₂ transistor has exhibited 3-4 times higher drain currents under the same operation condition. The field-effect mobility of the device is also enhanced to 3.41 cm²·V⁻¹·s⁻¹. The results have demonstrated that with a 2-D material buffer layer underneath the 2-D material channel layer, the influence from the dangling bonds/defects on the dielectric surface can be depressed. Lower carrier scattering and therefore, higher field-effect mobility is observed for the transistor. However, as shown in FIG. 8, a clear hysteresis loop is still observed for the device.

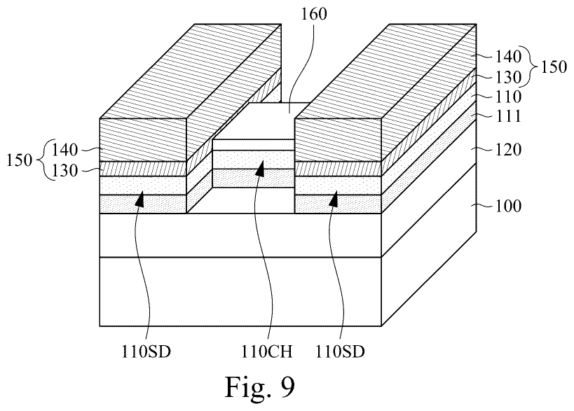

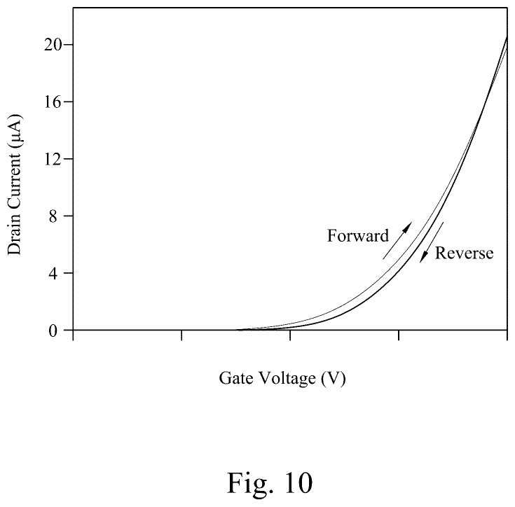

FIG. 9 illustrates a semiconductor device in accordance with some embodiments of the present disclosure. FIG. 10 shows an experiment result of a semiconductor device in accordance with some embodiments of the present disclosure. It is noted that some elements of FIG. 9 are similar to those described with respect to FIGS. 1A to 1D and FIG. 7, such elements are labeled the same and relevant details are not repeated for brevity.

As discussed above with respect to FIGS. 7 and 8, although inserting the 2-D material buffer layer 111 between the dielectric layer 120 and the 2-D material channel layer 110 can improve the device performance, a clear hysteresis loop is still observed for the device (see FIG. 8). A possible mechanism responsible for the hysteresis of the device under forward and reverse biases may be the interface between air and 2-D material channel. To address this issue, a passivation layer may be formed covering the 2-D material channel layer 110, so as to isolate the 2-D material channel layer 110 from atmospheric condition.

In FIG. 9, a passivation layer 160 is formed over the 2-D material channel layer 110 after the source/drain electrodes 150 are formed. As a result, the passivation layer 160 may cover and may be in contact with the channel region 110CH of the 2-D material channel layer 110. It is noted that although the passivation layer 160 is illustrated only covering the top surface of the 2-D material channel layer 110, the passivation layer 160 may also extend to sidewalls of the 2-D material channel layer 110 and sidewalls of the 2-D material buffer layer 111.

The passivation layer 160 may include dielectric material, such as aluminum oxide (Al₂O₃) , silicon dioxide (e.g., SiO₂) , or other suitable dielectric material. In other embodiments, the passivation layer 160 may include high-k dielectric material, such as HfO₂. In some embodiments wherein the passivation layer 160 is made of aluminum oxide (Al₂O₃) , the thickness of the Al₂O₃ passivation layer 160 is about 30 nm. In some embodiments, the 30 nm Al₂O₃ passivation layer 160 may be formed by depositing a 5 nm Al₂O₃ layer using a physical deposition process (e.g., e-beam evaporation) and followed by a 25 nm Al₂O₃ layer using a chemical deposition process (e.g., ALD). Because the surface of the 2-D material channel layer 110 lacks dangling bonds to provide nucleation sites for the dielectric materials of the passivation layer 160. If the dielectric material (e.g., Al₂O₃) is formed by a chemical deposition, such as ALD process, the precursors may be hard to uniformly distribute over the surface of the 2-D material channel layer 110. However, due to the nature of physical deposition, the vaporized materials or ionized materials may be “dropped over” the surface of the 2-D material channel layer 110, and may include better coverage over the 2-D material channel layer 110 than using a chemical deposition. Accordingly, a thin layer of passivation layer 160 formed by physical deposition may act as a seed layer for the following deposited thick layer of the passivation layer 160, such that the entire passivation layer 160 may have better coverage and uniformity over the 2-D material channel layer 110.

The transfer curve of the transistor of FIG. 9 with the passivation layer 160 (e.g., 30 nm Al₂O₃) is shown in FIG. 10. With the passivation layer 160, the hysteresis loop of the device under forward and reverse biases is significantly reduced. Higher drain currents and higher field-effect mobility 7.22 cm²·V⁻¹·s⁻¹ are also observed for the device. The results have demonstrated that water or oxygen molecules attached to the 2-D material channel surface may introduce electron scattering and charge trapping on the 2-D material channel surface.

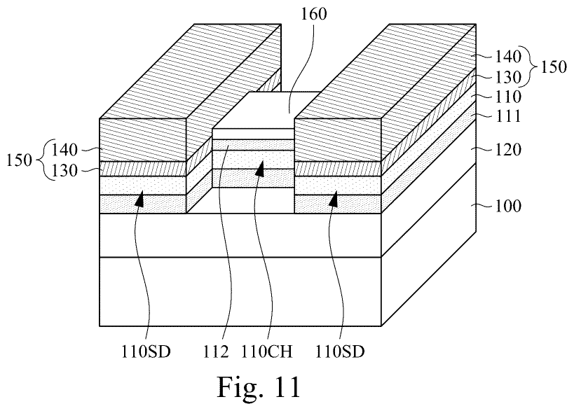

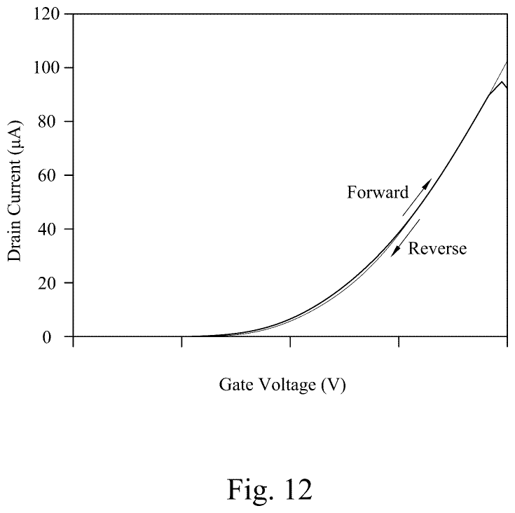

FIG. 11 illustrates a semiconductor device in accordance with some embodiments of the present disclosure. FIG. 12 shows an experiment result of a semiconductor device in accordance with some embodiments of the present disclosure. It is noted that some elements of FIG. 11 are similar to those described with respect to FIGS. 1A to 1D, FIG. 7, and FIG. 9, such elements are labeled the same and relevant details are not repeated for brevity.

As discussed above with respect to FIGS. 9 and 10, the passivation layer 160 formed covering the 2-D material channel layer 110 may significantly improve the device performance, which indicates that water or oxygen molecules attached to the 2-D material channel is the main mechanism responsible for the hysteresis observed for the transistor. However, the enhanced field-effect mobility value of the transistor also suggest that the electron scattering will also occur at the interface between 2-D material channel layer 110 (e.g., MoS₂) and the passivation layer 160 (e.g., dielectric material). To address this issue, a device with additional 2-D material buffer layer on top of the 2-D material channel is fabricated.

In FIG. 11, a 2-D material buffer layer 112 is formed over the 2-D material channel layer 110 after the formation of the source/drain electrodes 150 and prior to the formation of the passivation layer 160 as discussed in FIG. 9. In greater detail, the 2-D material buffer layer 112 covers the channel region 110CH of the 2-D material channel layer 110. On the other hand, the source/drain regions 110SD of the 2-D material channel layer 110 are covered by the source/drain electrodes 150, and are free of coverage by the 2-D material buffer layer 112. In some embodiments, the 2-D material buffer layer 112 and the 2-D material channel layer 110 may be patterned together during the channel definition process as discussed in FIG. 1D, and thus the 2-D material buffer layer 112 may include substantially a same profile as the channel region 110CH of the 2-D material channel layer 110.

In some embodiments, the 2-D material buffer layer 112 may include a same material as the 2-D material channel layer 110, such as MoS₂, MoSe₂, MoTe₂, WS₂, WSe₂, WTe₂, or the like. In some other embodiments, the 2-D material buffer layer 112 may include a different material than the 2-D material channel layer 110. For example, the 2-D material buffer layer 112 may include a different TMD than the 2-D material channel layer 110. In some embodiments, the 2-D material channel layer 110 is made of MoS₂, and the 2-D material buffer layer 112 is made of MoS₂. In other embodiments, the 2-D material buffer layer 112 may include hBN. In some embodiments, the 2-D material buffer layer 112 may include 1-10 monolayer(s).

In some embodiments, the 2-D material buffer layer 112 may be formed using an atomic layer deposition (ALD). In other embodiments, the 2-D material buffer layer 112 may be formed using a PDMS stamping followed by an annealing process to reduce a surface roughness of the 2-D material buffer layer 112. That is, when the 2-D material channel layer 110 and the 2-D material buffer layers 111 and 112 are all formed by PDMS stamping, a first PDMS stamping is performed to form the 2-D material buffer layer 111 over the dielectric layer 120, and a first annealing process is performed to smooth out the 2-D material buffer layer 111. Then, a second PDMS stamping is performed to form the 2-D material channel layer 110 over the 2-D material buffer layer 111, and a second annealing process is performed to smooth out the 2-D material channel layer 110. Afterwards, a third PDMS stamping is performed to form the 2-D material buffer layer 112 over the 2-D material channel layer 110, and a third annealing process is performed to smooth out the 2-D material buffer layer 112. Such method may ensure better film qualities for both the 2-D material channel layer 110 and the 2-D material buffer layers 111 and 112.

In the embodiments of FIG. 11, because the 2-D material buffer layer 112 is formed covering the 2-D material channel layer 110, the passivation layer 160 may cover and may be in contact with top surface of the 2-D material buffer layer 112. It is noted that although the passivation layer 160 is illustrated only covering the top surface of the 2-D material buffer layer 112, the passivation layer 160 may also extend to sidewalls of the 2-D material buffer layer 112, sidewalls of the 2-D material channel layer 110, and sidewalls of the 2-D material buffer layer 111.

The transfer curve of the device at V_{DS}=1.0 V is shown in FIG. 12. Compared with the device discussed in FIGS. 9 and 10, even higher drain currents and hysteresis-free transfer curves are observed for the device with a 2-D material buffer layer on top of the 2-D material channel. Good device performances with high field-effect mobility value of 22.70 cm²·V⁻¹·s⁻¹ and >10⁵ ON/OFF ratio are also observed for the device.

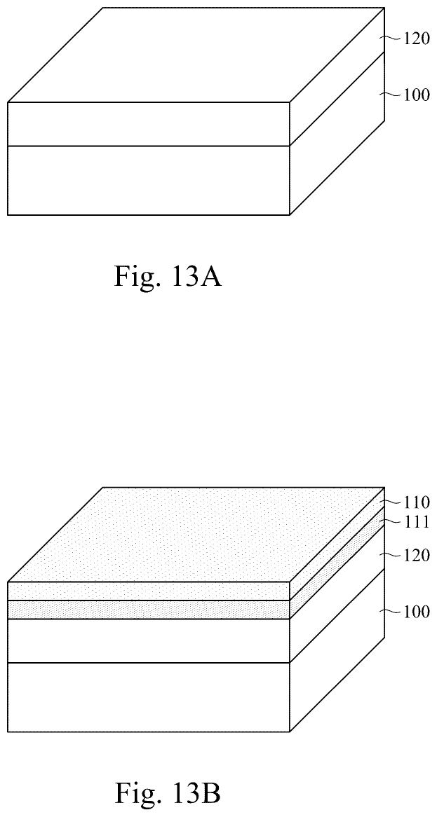

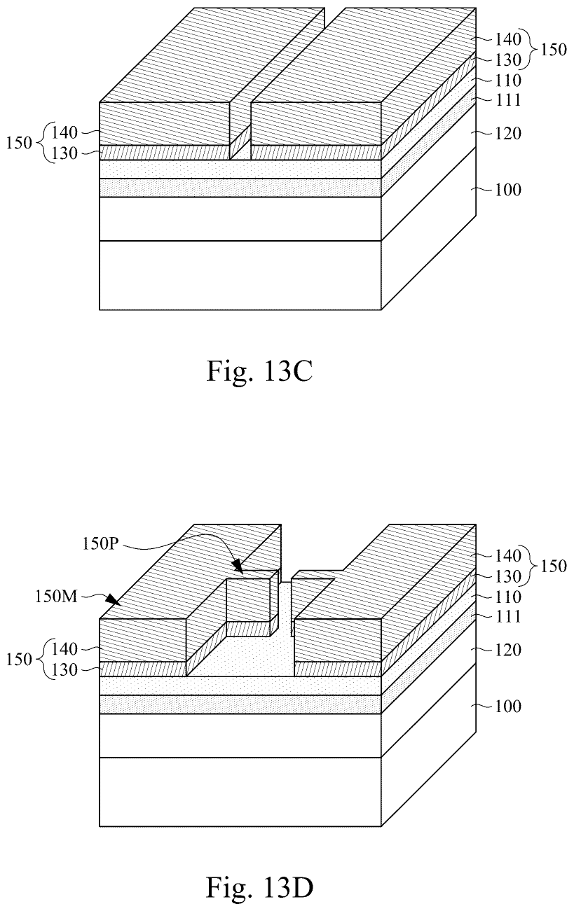

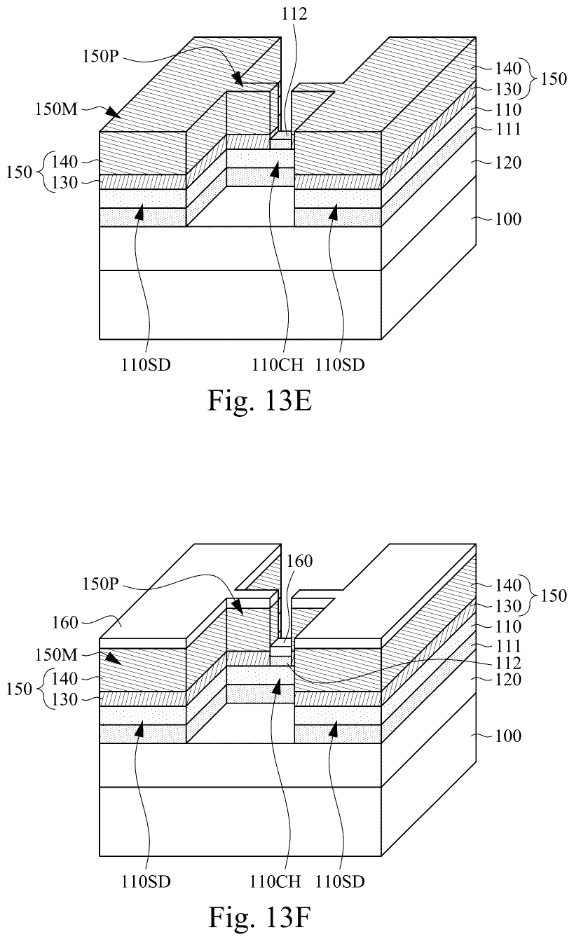

FIGS. 13A to 13F illustrate a semiconductor device in various stages of fabrication in accordance with some embodiments of the present disclosure. It is noted that some elements of FIGS. 13A to 13F are similar to those described above, such elements are labeled the same, and relevant details are not repeated for brevity.

Reference is made to FIG. 13A. Shown there is a substrate 100. A dielectric layer 120 is formed over the substrate 100. In some embodiments, the substrate 100 may serve as a gate electrode of a transistor and the dielectric layer 120 may act a gate dielectric layer of a transistor. Accordingly, the conductive substrate 100 can also be referred to as a gate electrode, and the dielectric layer 120 can also be referred to as a gate dielectric layer. In some embodiments, the dielectric layer 120 and the substrate 100 can be collectively referred to as a gate structure.

Reference is made to FIG. 13B. A 2-D material buffer layer 111 and a 2-D material channel layer 110 are sequentially formed over the dielectric layer 120. In some embodiments, the 2-D material buffer layer 111 and the 2-D material channel layer 110 may be made of a same material. In some embodiments, the 2-D material buffer layer 111 and the 2-D material channel layer 110 may be formed by suitable deposition process, such as an ALD process as discussed above. In other embodiments, each of the 2-D material buffer layer 111 and the 2-D material channel layer 110 may be formed by PDMS stamping and followed by an annealing process as discussed above.

Reference is made to FIG. 13C. Source/drain electrodes 150 are formed over the 2-D material channel layer 110. 112. In some embodiments, each of the source/drain electrodes 150 includes a first metal layer 130 and a second metal layer 140 over the first metal layer 130.

Reference is made to FIG. 13D. The source/drain electrodes 150 are patterned, such that each of the source/drain electrodes 150 includes a protruding portion 150P laterally protruding from the main portion 150M of each source/drain electrode 150. In some embodiments, the protruding portion 150P of the source/drain electrode 150 is narrower than the main portion of the source/drain electrode 150 along a direction that is substantially perpendicular to a current flow direction.

Reference is made to FIG. 13E. A 2-D material buffer layer 112 is formed blanket over the substrate 100. Then, the 2-D material buffer layer 112, the 2-D material channel layer 110, and the 2-D material buffer layer 111 are patterned. In greater detail, portion of the 2-D material channel layer 110 and portion of the 2-D material buffer layer 111 exposed through the source/drain electrodes 150 are patterned. In greater detail, the patterning process is performed such that the portion of the 2-D material channel layer 110 exposed through the source/drain electrodes 150 is narrowed down along a direction that is substantially perpendicular to a current flow direction, so as to define the channel region 110CH of the 2-D material channel layer 110. The 2-D material buffer layer 111 is patterned together with the 2-D material channel layer 110, and thus the 2-D material buffer layer 111 may include substantially a same profile as the 2-D material channel layer 110. On the other hand, the 2-D material buffer layer 112 may include substantially a same profile as the channel region 110CH of the 2-D material channel layer 110. In some embodiments, the patterning process may include e-beam lithography.

In some embodiments, the 2-D material buffer layer 112 may be formed by suitable deposition process, such as an ALD process as discussed above. In other embodiments, the 2-D material buffer layer 112 may be formed by PDMS stamping and followed by an annealing process as discussed above.

Reference is made to FIG. 13F. A passivation layer 160 is formed over the 2-D material buffer layer 112. As a result, the passivation layer 160 may cover and may be in contact with top surface of the 2-D material buffer layer 112. It is noted that although the passivation layer 160 is illustrated only covering the top surface of the 2-D material buffer layer 112, the passivation layer 160 may also extend to sidewalls of the 2-D material buffer layer 112, sidewalls of the 2-D material channel layer 110, and sidewalls of the 2-D material buffer layer 111. In some embodiments, the passivation layer 160 may also cover top surfaces of the source/drain electrodes 150.

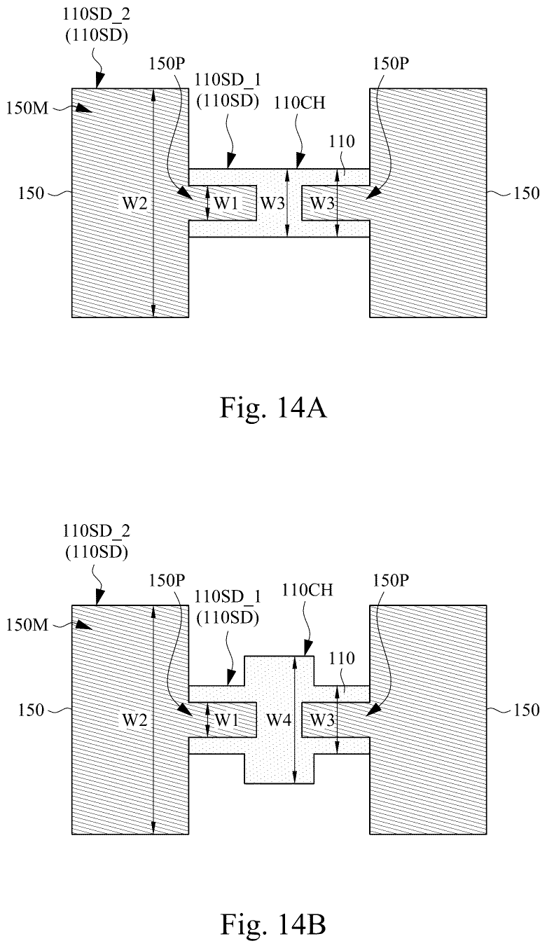

FIGS. 14A to 14B illustrate semiconductor devices in accordance with some embodiments of the present disclosure. In greater detail, FIGS. 14A and 14B are top views of the device shown in FIG. 13F in accordance with some embodiments. It is noted that only the source/drain electrodes 150 and the 2-D material channel layer 110 are illustrated in the top views of FIGS. 14A and 14B for clarity.

Reference is made to FIG. 14A. Each of the source/drain electrodes 150 includes a main portion 150M and a protruding portion 150P extending from the main portion 150M along the X-direction. In some embodiments, along the Y-direction, a width W1 of the protruding portion 150P is less than a width W2 of the main portion 150M. In some embodiments, the width W1 about 500 nm. In some embodiments, the distance between the protruding portion 150P of one source/drain electrode 150 and the protruding portion 150P of another source/drain electrode 150 is about 660 nm.

On the other hand, the 2-D material channel layer 110 includes a channel region 110CH and source/drain regions 110SD on opposite sides of the channel region 110CH. In some embodiments, each of the source/drain regions 110SD may include a first portion 110SD_1 that is vertically below the protruding portion 150P of the respectively source/drain electrode 150, and a second portion 110SD_2 that is vertically below the main portion 150M of the respectively source/drain electrode 150. In some embodiments, the first portion 110SD_1 is narrower than the second portion 110SD_2 along the Y-direction. Moreover, the first portion 110SD_1 of the source/drain regions 110SD has a width W3 along the Y-direction, and the channel region 110CH also includes a width W3 along the Y-direction. That is, the first portion 110SD_1 of the source/drain regions 110SD and the channel region 110CH include substantially a same width. In some embodiments, the width W3 is greater than the width W1, and is less than the width W2.

Reference is made to FIG. 14B. FIG. 14B is different from FIG. 14A, in that the channel region 110CH includes a width W4 along the Y-direction that is greater than the width W3 of the first portion 110SD_1 of the source/drain regions 110SD. This is because during the channel definition process as discussed in FIG. 13E, the channel region 110CH may not be protected by the source/drain electrodes 150, and thus the wider channel region 110CH may provide sufficient buffer for the etching process.

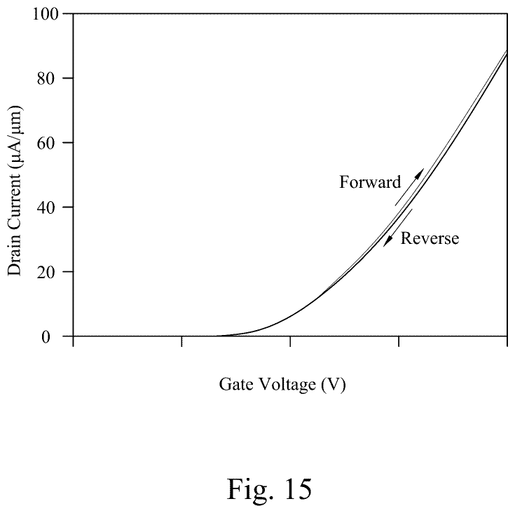

In some embodiments where the 2-D material channel layer 110 is made of MoS₂, polycrystalline MoS₂ films instead of single-crystal MoS₂ films are obtained for the wafer-scale MoS₂ samples, the other possible mechanism, which may influence the device performances, may come from the carrier scatterings at the MoS₂ grain boundaries. To investigate this phenomenon, a device with reduced line width is provided. After the source/drain electrodes 150 are formed, extended electrodes (e.g., the protruding portion 150P) from the source/drain electrodes 150 are fabricated. To avoid the excess current flow from the large source/drain electrodes 150 to the channel region 110CH, channel region 110CH and source/drain electrodes 150 with reduced line widths are formed. The transfer curve of the device at V_{DS}=1.0 V is shown in FIG. 15. Compared with the device with larger line width (see FIGS. 11 and 12), even higher field-effect mobility value 63.80 cm²·V⁻¹·s⁻¹ and >10⁶ ON/OFF ratio are observed for the device, which is attributed to the reduced carrier scattering in the polycrystalline MoS₂ channel. A high drain current density ˜90 μA/μm is also observed for the device. The results have also demonstrated that although the crystallinity of the MoS₂ film is one major issue for its device performances.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a semiconductor device with 2-D material channel layer. In some embodiments, the 2-D material channel layer may be formed by ALD process or by PDMS stamping with annealing process, so as to reduce surface roughness of the 2-D material channel, and will further reduce device performance. In other embodiments, 2-D material buffer layers may be formed on top and bottom of the 2-D material channel layer, so as to prevent affect from dangling bonds/defects/electron scattering at the interface between the 2-D material channel layer and dielectric layer. In other embodiments, a passivation layer may be formed on top of the 2-D material channel layer to prevent the 2-D material channel layer from exposure to the air. In other embodiments, line widths of the 2-D material channel layer and the source/drain electrodes are reduced to further improve device performance.

In some embodiments of the present disclosure, a method includes forming a gate electrode in contact with a gate dielectric layer; forming a first 2-D material buffer layer over the gate dielectric layer; forming a 2-D material channel layer over the first 2-D material buffer layer; and forming source/drain electrodes over source/drain regions of the 2-D material channel layer.

In some embodiments, the method further includes forming a second 2-D material buffer layer over the 2-D material channel layer.

In some embodiments, the first and second 2-D material buffer layers are made of a different 2-D material than the 2-D material channel layer.

In some embodiments, wherein the 2-D material channel layer is in contact with the source/drain electrodes.

In some embodiments, the 2-D material channel layer is formed by performing a first polydimethylsiloxane (PDMS) stamping process to transfer the 2-D material channel layer to the first 2-D material buffer layer; and performing a first annealing process to reduce a surface roughness of the 2-D material channel layer.

In some embodiments, the first 2-D material buffer layer is formed by performing a second polydimethylsiloxane (PDMS) stamping process to transfer the first 2-D material buffer layer to the gate dielectric layer; and performing a second annealing process to reduce a surface roughness of the first 2-D material buffer layer.

In some embodiments, the method further includes forming a passivation layer covering a top surface of the 2-D material channel layer after forming the source/drain electrodes.

In some embodiments of the present disclosure, a method includes forming a gate electrode in contact with a gate dielectric layer; forming a 2-D material channel layer over the gate dielectric layer, wherein the 2-D material channel layer is formed by forming the 2-D material channel layer on a first carrier; transferring the 2-D material channel layer from the first carrier to the gate dielectric layer; and performing a first annealing process to reduce a surface roughness of the 2-D material channel layer; and forming source/drain electrodes over source/drain regions of the 2-D material channel layer.

In some embodiments, the method further includes forming a 2-D material buffer layer over the gate dielectric layer prior to forming the 2-D material channel layer, wherein the 2-D material channel layer is formed in contact with the 2-D material buffer layer.

In some embodiments, the method further includes forming a 2-D material buffer layer over the 2-D material channel layer after forming the source/drain electrodes.

In some embodiments, the method further includes forming a dielectric passivation layer covering a top surface of the 2-D material channel layer after forming the source/drain electrodes.

In some embodiments, the method further includes performing a first patterning process to an exposed portion of the 2-D material channel layer after forming the source/drain electrodes, so as to narrow down the 2-D material channel layer along a first direction.

In some embodiments, the method further includes performing a second patterning process to the source/drain electrodes prior to performing the first patterning process, such that each of the source/drain electrodes comprise a main portion and a protruding portion extending from the main portion along a second direction perpendicular to the first direction.

In some embodiments, after the first patterning process is complete, the 2-D material channel layer has a channel region between the source/drain electrodes, and a source/drain region below the protruding portion of one of the source/drain electrodes, wherein the channel region is wider than the source/drain region along the first direction.

In some embodiments, the protruding portion is narrower than the main portion along the first direction.

In some embodiments of the present disclosure, a semiconductor device includes a gate electrode, a gate dielectric layer in contact with the gate electrode, a first 2-D material buffer layer over the gate dielectric layer, a 2-D material channel layer over the first 2-D material buffer layer, and source/drain electrodes over the 2-D material channel layer.

In some embodiments, the first 2-D material buffer layer is made of a different 2-D material than the 2-D material channel layer.

In some embodiments, the semiconductor device further includes a second 2-D material buffer layer over the 2-D material channel layer.

In some embodiments, each of the source/drain electrodes comprise a main portion and a protruding portion extending from the main portion along a first direction, and the protruding portion is narrower than the main portion along a second direction perpendicular to the first direction.

In some embodiments, the 2-D material channel layer has a channel region between the source/drain electrodes, and a source/drain region below the protruding portion of one of the source/drain electrodes, wherein the channel region is wider than the source/drain region along the second direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a gate electrode in contact with a gate dielectric layer;
forming a first 2-D material buffer layer over the gate dielectric layer;
forming a 2-D material channel layer over the first 2-D material buffer layer; and
forming source/drain electrodes over source/drain regions of the 2-D material channel layer.

2. The method of claim 1, further comprising forming a second 2-D material buffer layer over the 2-D material channel layer.

3. The method of claim 2, wherein the first and second 2-D material buffer layers are made of a different 2-D material than the 2-D material channel layer.

4. The method of claim 2, wherein the 2-D material channel layer is in contact with the source/drain electrodes.

5. The method of claim 1, wherein the 2-D material channel layer is formed by:
performing a first polydimethylsiloxane (PDMS) stamping process to transfer the 2-D material channel layer to the first 2-D material buffer layer; and
performing a first annealing process to reduce a surface roughness of the 2-D material channel layer.

6. The method of claim 5, wherein the first 2-D material buffer layer is formed by:
performing a second polydimethylsiloxane (PDMS) stamping process to transfer the first 2-D material buffer layer to the gate dielectric layer; and
performing a second annealing process to reduce a surface roughness of the first 2-D material buffer layer.

7. The method of claim 1, further comprising forming a passivation layer covering a top surface of the 2-D material channel layer after forming the source/drain electrodes.

8. A method, comprising:
forming a gate electrode in contact with a gate dielectric layer;
forming a 2-D material channel layer over the gate dielectric layer, wherein the 2-D material channel layer is formed by:
forming the 2-D material channel layer on a first carrier;
transferring the 2-D material channel layer from the first carrier to the gate dielectric layer; and
performing a first annealing process to reduce a surface roughness of the 2-D material channel layer; and
forming source/drain electrodes over source/drain regions of the 2-D material channel layer.

9. The method of claim 8, further comprising forming a 2-D material buffer layer over the gate dielectric layer prior to forming the 2-D material channel layer, wherein the 2-D material channel layer is formed in contact with the 2-D material buffer layer.

10. The method of claim 8, further comprising forming a 2-D material buffer layer over the 2-D material channel layer after forming the source/drain electrodes.

11. The method of claim 8, further comprising forming a dielectric passivation layer covering a top surface of the 2-D material channel layer after forming the source/drain electrodes.

12. The method of claim 8, further comprising performing a first patterning process to an exposed portion of the 2-D material channel layer after forming the source/drain electrodes, so as to narrow down the 2-D material channel layer along a first direction.

13. The method of claim 12, further comprising performing a second patterning process to the source/drain electrodes prior to performing the first patterning process, such that each of the source/drain electrodes comprise a main portion and a protruding portion extending from the main portion along a second direction perpendicular to the first direction.

14. The method of claim 13, wherein after the first patterning process is complete, the 2-D material channel layer has a channel region between the source/drain electrodes, and a source/drain region below the protruding portion of one of the source/drain electrodes, wherein the channel region is wider than the source/drain region along the first direction.

15. The method of claim 13, wherein the protruding portion is narrower than the main portion along the first direction.

16. A semiconductor device, comprising:
a gate electrode;
a gate dielectric layer in contact with the gate electrode;
a first 2-D material buffer layer over the gate dielectric layer;
a 2-D material channel layer over the first 2-D material buffer layer; and
source/drain electrodes over the 2-D material channel layer.

17. The semiconductor device of claim 16, wherein the first 2-D material buffer layer is made of a different 2-D material than the 2-D material channel layer.

18. The semiconductor device of claim 17, further comprising a second 2-D material buffer layer over the 2-D material channel layer.

19. The semiconductor device of claim 16, wherein each of the source/drain electrodes comprise a main portion and a protruding portion extending from the main portion along a first direction, and the protruding portion is narrower than the main portion along a second direction perpendicular to the first direction.

20. The semiconductor device of claim 19, wherein the 2-D material channel layer has a channel region between the source/drain electrodes, and a source/drain region below the protruding portion of one of the source/drain electrodes, wherein the channel region is wider than the source/drain region along the second direction.
